(19) United States
(12) Patent Application Publication
(10) Pub. No.: US 2008/0259536 A1
(43) Pub. Date: Oct. 23, 2008

(54) Handheld Electronic Processing Apparatus and an Energy Storage Accessory Fixable Thereto

(76) Inventors: Ah Hock Law, Singapore (SG); Tze Wei Henry Wong, Singapore (SG); Yen Jason Chin, Singapore (SG); Ji Woei Amos Foo, Singapore (SG)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 12/089,554

(22) PCT Filed: Oct. 10, 2005
(86) PCT No.: PCT/SG2005/000348

§ 371 Date: Apr. 8, 2008

(51) Int. Cl. H05K 5/00

(52) U.S. Cl. 361/679

(57) ABSTRACT

A PDA (10) and an external battery pack (100) for fitting thereto. The battery pack (100) can be used to supplement an internal battery of the PDA (10). The PDA (10) has electrical contacts (40) that are for contacting electrical contacts (140) of the battery pack (100). The electrical contacts (40) of the PDA (10) are heat staked into material of a casing (20) of the PDA (10) to provide sealing therebetween. Electrical contact between the contacts (40) of the PDA (10) and a PCB (50) contained therein is provided by a respective helical spring (46) that abuts each contact (40) and the PCB (50). This helps to maintain the contact in the event that the PDA (10) is dropped. The electrical contacts (140) of the battery pack (100) are insert moulded in casing thereof to provide sealing therebetween.

### FIELD OF THE INVENTION

This invention relates to handheld electronic processing apparatus and to an energy storage accessory fixable thereto. Particularly, but not exclusively, this invention relates to a personal digital assistant (PDA) and to an external battery pack fixable thereto.

### BACKGROUND TO THE INVENTION

Personal digital assistants (PDAs) are handheld, portable, computing devices that provide at least some of the features of a conventional desktop personal computer. Such devices are intended to be of use to those who are not able, or for whom it is inconvenient, to access a conventional desktop personal computer. In order to be truly portable, PDAs include a dedicated, portable, power-source therein, usually in the form of a battery. One problem associated with PDAs is therefore that they can only be operated for as long as the battery continues to provide electrical power to the PDA.

An object of this invention is to address this problem.

A form of PDA is also used in industrial environments, such as manufacturing facilities and industrial storage facilities. This form of PDA will hereinafter be referred to as an “industrial PDA”. In facilities such as these, industrial PDAs are used for tasks such as recording operational data from manufacturing machines and for stock control purposes. The environment in which industrial PDAs are used is therefore a much harsher environment than that to which a conventional PDA might be exposed. The industrial PDA is likely to be exposed to corrosive materials, airborne particles and contaminants; and mechanical impact, vibration and wear. As a result, industrial PDAs must be of more rugged design that conventional PDAs if they are to be of use.

One way in which the suitability of industrial PDAs to their intended environment can be indicated is by way of an ingression protection (IP) rating. This rating is a measure of the degree of protection a PDA has against the ingression of liquids and particles. PDAs can also be assessed in terms of the height of a vertical drop which the PDA can survive without substantial damage.

An object of certain embodiments of this invention is to provide a handheld device that addresses the first problem noted above and that is also suited for use in an industrial environment.

### SUMMARY OF THE INVENTION

According to one aspect of this invention, there is provided handheld electronic processing apparatus having a housing in which is housed internal energy storage means for supplying electrical energy to electrical components of the apparatus for operation thereof, the apparatus further including an energy storage accessory fixable to the apparatus to provide auxiliary electrical energy thereto.

By providing an energy storage accessory that is fixable to the apparatus to provide auxiliary energy thereto, it is possible to extend the time by which the handheld apparatus can be operated without having to replace or recharge the internal energy storage means.

Preferably the apparatus includes electrical contacts for contacting the accessory, whereby the electrical energy can be supplied to the electrical components of the apparatus, contact between the electrical contacts and the electrical components being via resiliently-deformable contact means, biased to maintain such contact.

According to a second of this invention, there is provided handheld electronic processing apparatus having a housing in which electrical components of the apparatus are housed and having electrical contacts for contacting an external energy storage accessory that is fixable to the apparatus, whereby electrical energy can be supplied to the apparatus; contact between the electrical contacts and the electrical components being via resiliently-deformable contact means, biased to maintain such contact.

The provision of resiliently deformable means in this way tends to maintain electrical contact between the contacts and the electrical components even when the apparatus is subject to mechanical shocks, such as being dropped. In addition, it allows soldered connections, which can break when subject to such shocks, to be avoided.

The electrical contacts may project through the housing, with material of the housing surrounding the contacts such that substantially no passage exits therebetween, thereby guarding against the ingress of extraneous matter into the housing.

According to a third aspect of this invention, there is provided handheld electronic processing apparatus and an energy storage accessory fixable to the apparatus to supply electrical energy thereto, each of the apparatus and the accessory having a respective housing in which respective electrical components are housed and through which respective electrical contacts project, the two sets of contacts arranged to contact one another when the accessory is fixed to the apparatus, wherein material of each housing surrounds the respective contacts such that substantially no passage exits therebetween, thereby guarding against the ingress of extraneous matter into the housings.

By providing substantially no passage between the contacts and the housing through which they project, unwanted entry of fluids and solid matter into the handheld apparatus or the energy storage accessory which may interfere with the functioning of the apparatus or accessory is resisted.

According to a fourth aspect of this invention, there is provided handheld electronic processing apparatus having a housing in which electrical components are housed and through which electrical contacts project for contacting electrical contacts of an energy storage accessory fixable to the apparatus for supplying electrical energy thereto, wherein material of the housing surrounds the respective contacts such that substantially no passage exits therebetween, thereby guarding against the ingress of extraneous matter into the housing.

According to a fifth aspect of this invention, there is provided an energy storage accessory for fixing to handheld data processing apparatus so as to supply electrical energy thereto, the accessory having a housing in which electrical components are housed and through which electrical contacts project for contacting electrical contacts of the apparatus, wherein material of the housing surrounds the respective contacts such that substantially no passage exits therebetween, thereby guarding against the ingress of extraneous matter into the housing.

The accessory may be fixable to the apparatus by screw fixing means. The screw fixing means may be arranged to pass through at least one aperture in material of the accessory and to screw into material of the apparatus, thereby urging the accessory into closer contact with the apparatus. The accessory may also include one or more projecting portion, each for placing inside a respective receiving portion of the apparatus so as to be held in place by that receiving portion. The or each receiving portion may be a loop of material attached to the housing of the apparatus into which a respective projecting portion may be inserted. Preferably, the or each projecting portion is tapered such that inserting it into the respective receiving portion forces the accessory into closer contact with the apparatus.

The contacts of the apparatus may be spaced apart from one another, thereby guarding against a short circuit between those contacts being created by adjacent liquid, moisture or particles. The contacts of the accessory may be spaced apart from one another, thereby guarding against a short circuit between those contacts being created by adjacent liquid, moisture or particles. Each contact of the apparatus may be spaced from the or each adjacent contact of the apparatus by at least 15 mm. The same may be true of the contacts of the accessory.

For the apparatus and/or the accessory, at least surrounding material of the housing may be formed around the contacts projecting therethrough. The contacts may be positioned in the respective housing by an insert moulding operation in which material of the respective housing is moulded around the contacts. The contacts may be positioned in the respective housing by heat staking operation in which the contacts are placed into position in the housing when the surrounding material is hot and soft.

In one embodiment, the contacts in the housing of the accessory are positioned by insert moulding. In one embodiment the contacts in the apparatus are positioned by heat staking.

At least one of the apparatus and the accessory may have sealing means on the housing thereof that extends around one or more of the contacts such that when the accessory is fixed to the apparatus the sealing means seals against the housing of the respective other of the apparatus and the accessory so that the or each contact is sealed from the surrounding environment.

The housing of at least one of the apparatus and the accessory may have a first part and a second part, the first part being fixable to the second part, and a gasket being provided to fit between the two parts, thereby sealing the first part to the second part. The first part may have a projecting portion that extends along the surface of that part that contacts the gasket. The second part may have a recess that also extends along the surface of that part that contacts the gasket, the recess being arranged to cooperate with the projecting portion of the first part such that the gasket is forced into the recess by the projecting portion when the first and second parts are brought together. One or both of the first and second part may include a groove running alongside the projecting portion and the recess, such that the compressed gasket can expand into the groove when the first and second part are brought together.

The apparatus may include a spring to provide contact between each contact of the apparatus and the electrical components housed in the housing thereof. The spring may be a helical spring with one end abutting the respective contact, or a conductor connector thereto, and the other end abutting a conductor inside the housing connected to the electrical components therein. The contact may have a spigot projecting therefrom inside the housing, with the helical spring positioned therearound, thereby providing location for the spring. The other end of the helical spring may abut a conducting trace of a printed circuit board (PCB).

The contacts of the apparatus may be shaped to cooperated with the contacts of the accessory. The contacts of one or the apparatus and the accessory may have a projecting part and the respective other contacts may have a cooperating recessed part, each projecting part being shaped for surface-to-surface contact with a respective recessed part. The projecting parts may each include a convex curved portion. The recessed parts may each include a cooperating concave curved portion. Preferably the contacts on the apparatus and/or the contacts on the accessory are resiliently deformable such that they are biased towards one another when the accessory is fixed to the apparatus.

The energy storage accessory may contain a battery. The battery may be permanently fitted in the accessory. The battery may be removable from the accessory. The energy storage accessory may contain a fuel cell.

### BRIEF DESCRIPTION OF THE DRAWINGS

Specific embodiments of this invention are described below by way of example only and with reference to the accompanying drawings, in which:

FIG. 1 is a front elevation view of a personal digital assistant (PDA) that embodies this invention;

FIG. 2 is a perspective view of the back of the PDA, showing a removable battery pack fixed thereto;

FIG. 3 is a similar perspective view to that of FIG. 2, but shows the battery pack detached and exploded such that components thereof are visible;

FIG. 4 is a sectional view of detail of the battery pack at a periphery thereof; and

FIG. 5 is a sectional view of detail of the PDA and the battery pack to show electrical contacts therebetween.

### SPECIFIC DESCRIPTION OF CERTAIN EXEMPLARY EMBODIMENTS

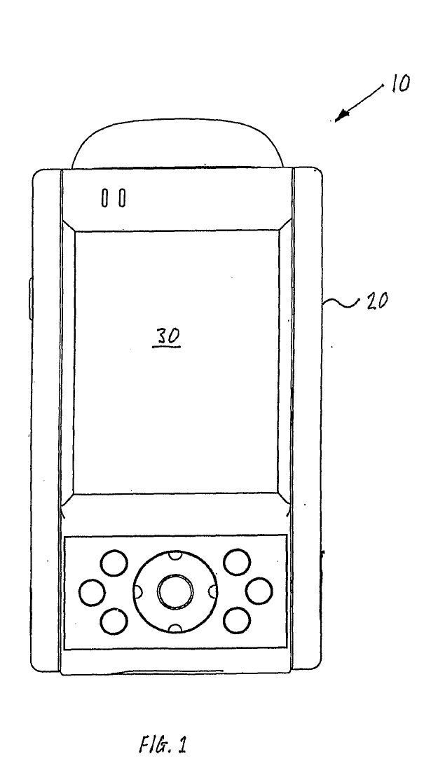

FIG. 1 shows handheld electronic processing apparatus in the form of a personal digital assistant (PDA) 10. The PDA 10 is shaped as a generally rectangular slab or tablet that is of a size which allows it to be gripped in a user's hand. A front face of the PDA 10 has a display screen 20 mounted therein. The display screen 20 is touch sensitive and in use acts as a graphical user interface. Accordingly, during use, the PDA 10 is positioned with the display screen facing towards the user. The PDA 10 has a plastic casing 30 that is designed to assist in protecting components of the PDA 10 from damage when the PDA 10 is subject to mechanical shocks, such as those resulting from the PDA 10 being dropped. The plastic casing 30 fits around the components of the PDA 10 so as to resist the ingress of extraneous matter. One such component is an internal battery (not shown) that provides electrical power for operating the PDA 10.

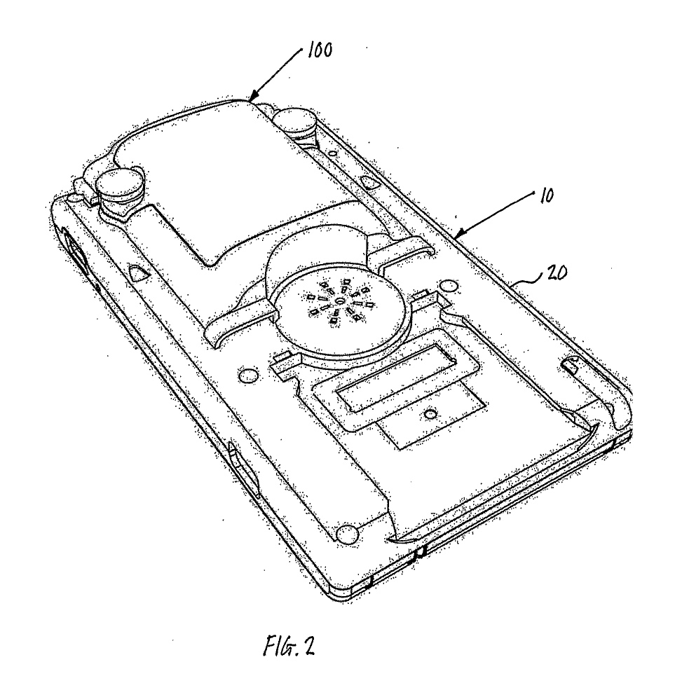

FIG. 2 shows the rear of the PDA 10 and shows an energy storage accessory in the form of an removable external battery pack 100 fitted to the PDA 10. The battery pack 100 has a similar slab-like shape to the PDA 10 but is only about half as long as the PDA 10. The external contours of the battery pack 100 are smooth to allow for comfortable gripping of the PDA 10 when the battery pack 100 is in place. The battery pack 100 is fitted to the rear face of the PDA so as to be at the top half thereof, the top of the PDA being the bit that is held uppermost during use. The battery pack 100 provides auxiliary electrical power for operating the PDA 10 to supplement that provided by the internal battery.

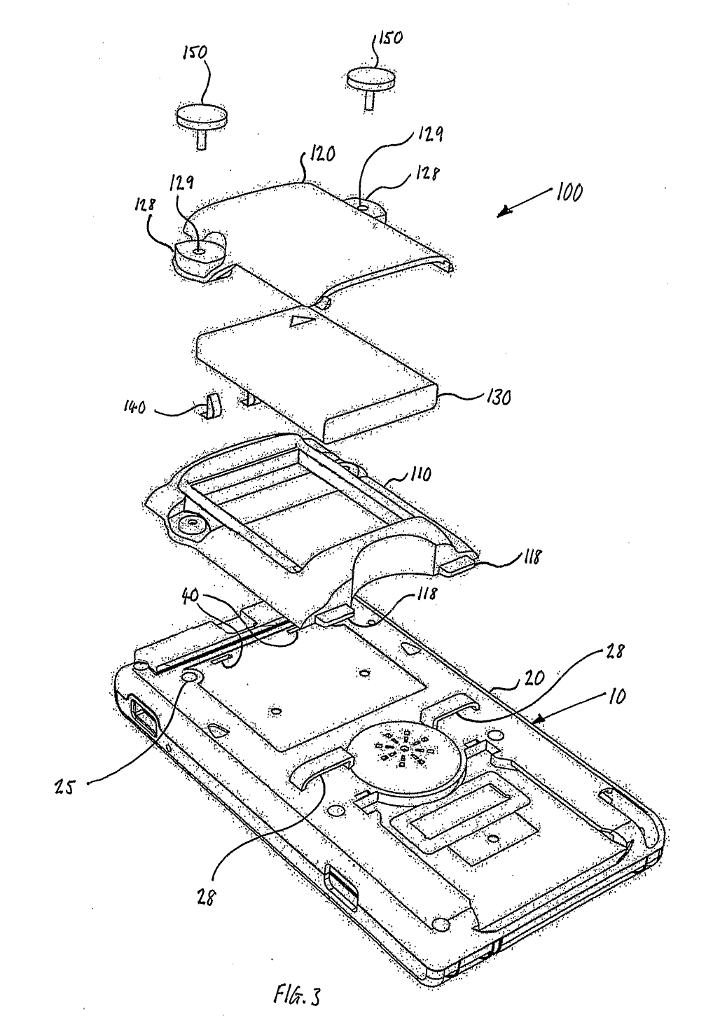

FIG. 3 shows the battery pack 100 detached from the PDA 10 and with components of the battery pack 100 spaced from one another such that each can be seen more clearly. With continued reference to FIG. 3, the battery pack 100 has a plastic casing that is made up of two halves: a bottom half 110 and a top half 120. The two halves 110, 120 of the battery casing fit together to enclose a battery 130. In this embodiment, the battery 130 is a conventional rechargeable battery of known composition.

The top half 120 of the battery pack 100 includes an integral raised wall 122 that extends around the periphery thereof and closely follows the external contours of the battery 120 when the battery 120 is placed therein. The bottom half 110 of the battery pack 100 includes a similar peripheral raised wall 112 which also follows the shape of the battery but is arranged so that the wall 122 in the top half 120 of the battery pack 100 fits inside it. A gasket (not shown in FIG. 3) is provided between the bottom half 110 and the top half 120 of the battery pack 100 to improve sealing between the two.

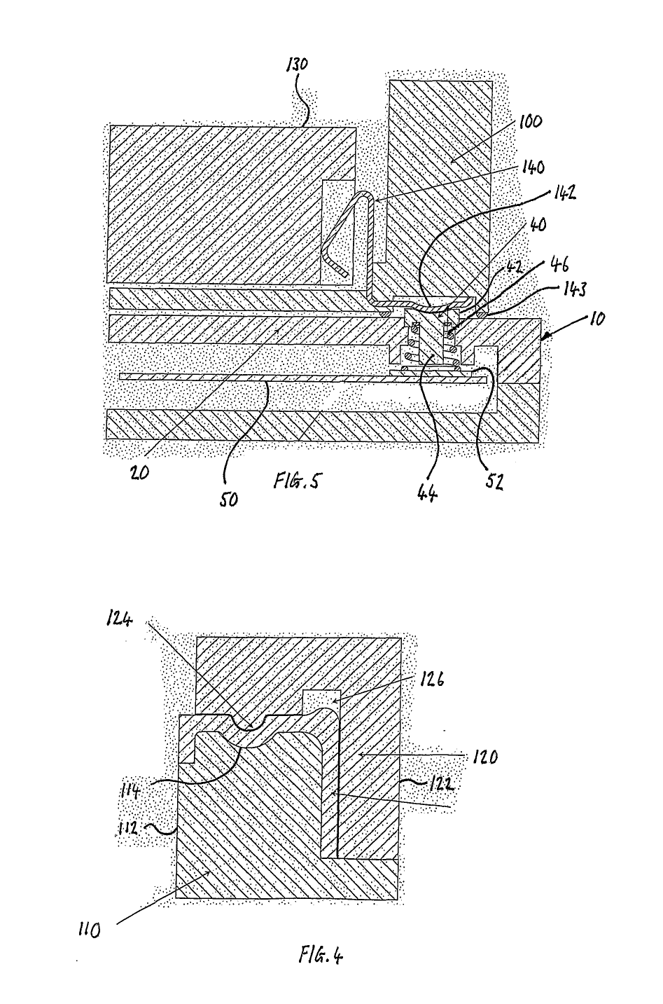

FIG. 4 shows the arrangement in more detail. From FIG. 4, it can be seen that the gasket 115 extends across the top of the peripheral wall 112 that projects from the bottom half 110 of the battery pack 100, and also extends down the inner side of that wall 112. With continued reference to FIG. 4, the top of the wall 112 of the bottom half 110 has a rounded channel 114 formed therein that extends all around the top of the wall 112. A cooperating rounded lip 124 projects from material of the top half 120 that comes fact-to-face with the wall 112 in the bottom half 110 when the two halve 110, 120 of the battery pack 100 are brought together. The lip 124 serves to push the gasket 115 into the groove 114 and thereby improves sealing between the two halves 110, 120. Sealing is further improved by the provision of a channel 126 in the top half 120. The channel 126 is positioned so as to be opposite the inner side of the wall 112 projecting from the bottom half 110. When the two halves 110, 120 are brought together and the gasket 115 squeezed therebetween, the gasket 115 can expand into the channel 126.

Returning to FIG. 3, the battery pack 100 also includes a pair of contacts 140. The contacts are spaced-apart metal strips that contact terminals of the battery 130 when the battery 130 is placed in casing of the battery pack 100. The contacts 140 are insert moulded in the bottom half 110 of the battery pack such that one end of each contact 140 projects through the material of the bottom half 110 so as to be exposed. The exposed ends of the contacts 150 each have a respective convex curved projecting portion (visible only in FIG. 5 at 142). The exposed ends of the contacts 140 are spaced apart in an attempt to minimise the risk of a short circuit occurring between those ends due to, for example, spilled water. A ring of sealant paste is applied to the outer face of the bottom half 110 of the battery pack 130 and extends around the exposed ends of the contacts 140 therein. The other end of each of the contacts 140 is for contacting the terminals of the battery 130. Each of these ends is formed so as to appear bent back on itself in a manner that causes it to act as a cantilevered spring. Thus, each of these ends of the contacts 140 is urged against a respective terminal of the battery 130 when the battery is accommodated in the battery pack 100.

The upper half 120 of the battery pack 100 includes, towards the end of the pack 100 that is adjacent the top of the PDA 10 when the pack 100 is fixed thereto, a pair of lugs 128, positioned opposite one another on opposite sides of the battery pack 100. Each lug 128 has an aperture 129 therethrough. A respective corresponding aperture 119 is also provided through the bottom half 110 of the battery pack 100 to align with each aperture 129 in the top half 120 when the two halves 110, 120 are brought together. A respective screw 150 with a large diameter, flat, knurled head is provided for each pair of corresponding apertures 119, 129.

The bottom half 110 of the battery pack, at the end that would be furthermost from the top of the PDA 10 when the battery pack 100 is fitted thereto, includes a pair of foot-like projections 118 projecting therefrom.

The PDA 10 includes a pair of stirrups 28 that project from the rear face of the PDA 10 and are each arranged to receive a respective foot-like projection 118 of the battery pack 100. The PDA 10 also includes a pair of holes 25, each of which has a screw thread formed therein and is arranged to receive and cooperated with a respective one of the screws 150 when the battery pack 100 is mounted in position on the rear of the PDA 10.

The PDA 10 also includes a pair of contacts 40 mounted in its rear face. Each of the contacts is positioned in the rear face so as to align with a respective one of contacts 140 of the battery pack 100, when the battery pack is mounted in position on the rear of the PDA 10.

FIG. 5 is a sectional view of the PDA 10 and the battery pack 100 that shows one of the contacts 40 in the PDA 10 and one of the contacts 140 in the battery pack 100 in cross section. With continued reference to FIG. 5, each contact 40 of the PDA 10 has a head portion 42 that is exposed and for contacting the exposed portion of a respective one of the contacts 140 of the battery pack 100, and has a spigot portion 44 that projects from the head portion 42 through the rear of the casing 20 of the PDA 10 into the inside thereof. The head portion 42 of each contact 40 has a curved convex recess formed therein. Each contact 40 is mounted in material of the casing 20 by heat staking the head portion 42 of the contact into that material. This involves pressing the head portion 42 into the surrounding material of the casing 20 when that material is hot and soft. When the material cools, the contact 40 is held fast thereby.

The casing 20 of the PDA 10 houses a printed circuit board (PCB) 50. The PCB 50 is positioned with respect to the contacts 40 such that the positive and ground conductor traces 52 thereof each extend under a respective one of the contacts 40 mounted in the casing 20 of the PDA 10. For each of the contacts 40, a respective helical spring 46 is provided. Each spring 46 is positioned around the spigot portion 44 of the respective contact 40 such that one end of the spring 46 abuts the head portion 42 of that contact 40 and the other end abuts the respective adjacent conductor trace 52 of the PCB 50. Each spring 46 is held in a compressed state between the respective contact 40 and conductor trace 52.

With reference to FIG. 3, the battery pack 100 is attached to the rear face of the PDA 10 by firstly placing each of the foot-like projections 118 into a respective stirrup 28 that projects from the rear face of the PDA 10. Each of the screws 150 is then screwed into the respective threaded hole 25 in the rear face of the PDA. Tightening the screws 150 urges the top half 120 of the battery towards the bottom half 110 thereof, and urges the battery pack 100 against the rear face of the PDA 10. Thus, the gasket 114 is squeezed against the two halves 110, 120 of the battery pack 100 as shown in FIG. 4.

As is shown in FIG. 5, when the battery pack 100 is urged against the PDA 10, the contacts 140 of the battery pack 100 are brought into contact with and urged against the contacts 40 of the PDA 10. In so doing, the convex projections 142 at the exposed ends of the contacts 140 of the battery pack 100 mate with the concave recesses in the head portions 42 of the contacts 40 of the PDA 10. Thus, there is area contact between the two sets of contacts 40, 140. As the two sets of contacts 40, 140 are forced together, the contacts 140 of the battery pack 100 bend and deflect slightly.

Should the PDA 10 with the battery pack fixed thereto be dropped, the springs 46 between the contacts 40 of the PDA and the PCB 50 thereof tends to absorb and shock and maintains electrical contact between the two. The same is true of the cantilevered ends of the contacts 140 of the battery pack 100 that contact the terminals of the battery 130 and the deflected ends of the contacts 140 of the battery pack 100 that contact and press against the contacts 40 of the PDA.

Should the PDA 10 with the battery pack 100 fixed there to come into contact with water, the insert moulding of the contacts 140 of the battery pack 100, and the heat staking of the contacts 40 of the PDA, mean that all the contacts are surrounded by material without any gap therebetween that could act as a passage for the water into the battery pack 100 or the PDA 10. The sealing paste 143 and the gasket 114 provide additional sealing.

That which is claimed:

1. A handheld electronic processing apparatus comprising a housing in which is housed internal energy storage means for supplying electrical energy to electrical components of the apparatus for operation thereof, the apparatus further comprising an energy storage accessory fixable to the apparatus to provide auxiliary electrical energy thereto.

2. An apparatus according to claim 1 further comprising electrical contacts for contacting the accessory, whereby the auxiliary electrical energy is supplied to the electrical components of the apparatus, contact between the electrical contacts and the electrical components being via resiliently-deformable contact means, biased to maintain such contact.

3. An apparatus according to claim 1 wherein the electrical components of the apparatus are housed within the housing, and the energy storage accessory is external and fixable to the apparatus.

4. An apparatus according to claim 2, wherein the electrical contacts project through the housing, with material of the housing surrounding the contacts such that substantially no passage exits therebetween, thereby guarding against the ingress of extraneous matter into the housing.

5. An apparatus according to claim 2 wherein the energy storage accessory comprises a housing such that each of the apparatus and the accessory have a respective housing in which respective electrical components are housed and through which respective electrical contacts project, the two sets of contacts arranged to contact one another when the accessory is fixed to the apparatus, wherein material of each housing surrounds the respective contacts such that substantially no passage exits therebetween, thereby guarding against the ingress of extraneous matter into the respective housings.

6. A handheld electronic processing apparatus having a housing in which electrical components are housed and through which electrical contacts project for contacting electrical contacts of an energy storage accessory fixable to the apparatus for supplying electrical energy thereto, wherein material of the housing surrounds the respective contacts such that substantially no passage exits therebetween, thereby guarding against the ingress of extraneous matter into the housing.

7. An energy storage accessory for fixing to a handheld data processing apparatus so as to supply electrical energy thereto, the accessory comprising a housing in which electrical components are housed and through which electrical contacts project for contacting electrical contacts of the apparatus, wherein material of the housing surrounds the respective contacts such that substantially no passage exits therebetween, thereby guarding against the ingress of extraneous matter into the housing.

8. An accessory according to claim 7, wherein the accessory is fixable to the apparatus by screw fixing means.

9. An accessory according to claim 7, wherein the accessory includes at least one projecting portion, each adapted for placing inside a respective receiving portion of the apparatus so as to be held in place by that receiving portion.

10. An accessory according to claim 9, wherein each receiving portion of the apparatus is a loop of material attached to the housing of the apparatus into which a respective projecting portion is configured to be inserted.

11. An accessory according to claim 9, wherein each projecting portion is tapered such that insertion thereof into the respective receiving portion forces the accessory into closer contact with the apparatus.

12. An apparatus according to claim 2, wherein the contacts of the apparatus are spaced apart from one another, thereby guarding against a short circuit between those contacts being created by at least one of adjacent liquid, moisture and particles.

13. An apparatus according to claim 5, wherein the contacts of the accessory are spaced apart from one another, thereby guarding against a short circuit between those contacts being created by at least one of adjacent liquid, moisture and particles.

14. An apparatus according to claim 5, wherein the surrounding material of the respective housing is formed around the contacts projecting therethrough.

15. An apparatus according to claim 14, wherein the contacts are positioned in the respective housing by an insert moulding operation in which material of the respective housing is moulded around the contacts.

16. An apparatus according to claim 14, wherein the contacts are positioned in the respective housing by heat staking operation in which the contacts are placed into position in the housing when the surrounding material is hot and soft.

17. An apparatus according to claim 5, wherein at least one of the apparatus and the accessory has sealing means on the housing thereof that extends around one or more of the contacts such that when the accessory is fixed to the apparatus the sealing means seals against the housing of the respective other of the apparatus and the accessory so that each contact is sealed from the surrounding environment.

18. An apparatus according to claim 5, wherein the housing of at least one of the apparatus and the accessory has a first part and a second part, the first part being fixable to the second part, and a gasket being provided to fit between the two parts, thereby sealing the first part to the second part.

19. An apparatus according to claim 18, wherein the first part has a projecting portion that extends along the surface of that part that contacts the gasket and the second part has a recess that also extends along the surface of that part that contacts the gasket, the recess being arranged to cooperate with the projecting portion of the first part such that the gasket is forced into the recess by the projecting portion when the first and second parts are brought together.

20. An apparatus according to claim 2 further comprising a spring to provide contact between each contact of the apparatus and the electrical components housed in the housing thereof.

21. An apparatus according to claim 20, wherein the spring is a helical spring with one end abutting one of the respective contact and a conductor connector connected thereto, and the other end abutting a conductor inside the housing connected to the electrical components therein.

22. An apparatus according to claim 21, wherein the contact has a spigot projecting therefrom inside the housing, with the helical spring positioned, therearound, thereby providing location for the spring.

23. An apparatus according to claim 22, wherein the other end of the helical spring abuts a conducting trace of a printed circuit board (PCB).

24. An apparatus according to claim 5, wherein the contacts of the apparatus and of the accessory are shaped to cooperate with one another.

25. An apparatus according to claim 24, wherein the contacts of one of the apparatus and the accessory have a projecting part and the respective other contacts have a cooperating recessed part, each projecting part being shaped for surface-to-surface contact with a respective recessed part.

26. An apparatus accessory according to claim 5, wherein the contacts on at least one of the apparatus and the contacts on the accessory are resiliently deformable such that they are biased towards one another when the accessory is fixed to the apparatus.
